(19) United States
(12) Patent Application Publication
(10) Pub. No.: US 2013/0319090 A1
(43) Pub. Date: Dec. 5, 2013

(54) TESTING OF SURFACE CRYSTALLINE CONTENT IN BULK AMORPHOUS ALLOY

(71) Applicants: Christopher D. PREST, San Francisco, CA (US); Matthew S. Scott, Campbell, CA (US); Stephen P. Zadesky, Portola Valley, CA (US); Richard W. Heley, Palo Alto, CA (US); Dermot J. Stratton, San Francisco, CA (US); Joseph C. Poole, San Francisco, CA (US); Theodore Andrew Waniuk, Lake Forest, CA (US)

(72) Inventors: Christopher D. PREST, San Francisco, CA (US); Matthew S. Scott, Campbell, CA (US); Stephen P. Zadesky, Portola Valley, CA (US); Richard W. Heley, Palo Alto, CA (US); Dermot J. Stratton, San Francisco, CA (US); Joseph C. Poole, San Francisco, CA (US); Theodore Andrew Waniuk, Lake Forest, CA (US)

(73) Assignee: Apple Inc., Cupertino, CA (US)

(21) Appl. No.: 13/483,265

(22) Filed: May 30, 2012

(51) Int. Cl. B23Q 17/20; B22D 2/00; G01Q 60/10; H01J 37/26; G01Q 60/24

(52) U.S. Cl. 73/78; 250/307; 850/33; 850/26; 164/4.1

(57) ABSTRACT

Provided in one embodiment is a method, comprising: forming a part comprising a bulk amorphous alloy, wherein the part comprises a sampling portion; determining a parameter related to the part by detecting by imaging on a surface of the sampling portion presence of crystals of the alloy; and evaluating the part based on the parameter.

### BACKGROUND

A large portion of the metallic alloys in use today are processed by solidification casting, at least initially. The metallic alloy is melted and cast into a metal or ceramic mold, where it solidifies. The mold is stripped away, and the cast metallic piece is ready for use or further processing. The as-cast structure of most materials produced during solidification and cooling depends upon the cooling rate. There is no general rule for the nature of the variation, but for the most part the structure changes only gradually with changes in cooling rate. On the other hand, for the bulk-solidifying amorphous alloys, the change between the amorphous state produced by relatively rapid cooling and the crystalline state produced by relatively slower cooling is one of kind rather than degree—the two states have distinct properties.

Bulk-solidifying amorphous alloys, or bulk metallic glasses (“BMG”), are a recently developed class of metallic materials. These alloys may be solidified and cooled at relatively slow rates, and they retain the amorphous, non-crystalline (i.e., glassy) state at room temperature. Amorphous alloys have many superior properties than their crystalline counterparts. However, if the cooling rate is not sufficiently high, crystals may form inside the alloy during cooling, so that the benefits of the amorphous state can be lost. For example, one challenge with the fabrication of bulk amorphous alloy parts is partial crystallization of the parts due to either slow cooling or impurities in the raw alloy material. Thus, ensuring a high degree of amorphicity (and, conversely, a low degree of crystallinity) can be important in the quality control of a BMG fabrication process.

Currently, the methods to detect the presence of a crystalline phase or to measure the degree of crystallinity can include bending test, x-ray radiography, and etching. However, all of these pre-existing techniques are destructive to the specimens examined. As a result, a BMG part (e.g., a casing) that is to be examined first needs to be significantly altered (e.g., sectioned and/or ground to a powder form), which can be undesirable.

Thus, a need exists to develop methods that can determine the degree of crystallinity of a BMG non-destructively, whereby facilitating quality control of its fabrication process.

### SUMMARY

All publications, patents, and patent applications cited in this Specification are hereby incorporated by reference in their entirety.

One embodiment provided herein describes quality control testing of bulk amorphous alloy (BAA) materials, or, alternatively, bulk metallic glass (BMG) materials. Quality herein in some embodiments may refer to a material property, such as a percentage of crystallinity.

One embodiment is related to evaluating a bulk amorphous alloy material through optical inspection. A BMG test sample may be formed as a detachable part from the main body of the BMG sample. For example, the detachable part may be formed as a protrusion from the main body of the BMG sample, which may be severed from the protrusion. The severing may be performed by breaking, sawing, cutting, or some any other way of severing. The separable detachable part may be located at the portion of the BMG material that exhibits a lower cooling rate than the rest of the body. For example, if a BMG sample were formed as a rod or as a bar, the detachable part may be formed to protrude from a center of one of the faces of the rod or bar, as shown in FIG. 3(a). The detachable portion 12 can be a sampling portion on which the inspection is carried out. The sampling portion can protrude from the main body the BMG sample material II. Forming the detachable part at that location may allow the interior or center of a cross section 123 in FIG. 3(b) to be examined. It can be worth examining the interior region because it is usually the place undergoing the slowest cooling, thereby being the place where a crystalline phase of the alloy is not likely to occur. Therefore, in some embodiments, the center, interior region, can provide a good indicator of the overall quality of the sampling portion with respect to the presence of crystals, and, by extension, the BMG sample as a whole.

In one embodiment, the sampling portion of the BMG sample may be examined through optical inspection. The inspection may survey the sample to detect the presence of crystal(s). The crystal(s) may take the form of crystalline precipitates. The optical inspection may examine the entire BMG sample, or may focus on only a portion of the material, such as the sampling portion, such as an interior exposed after being cross-sectioned such as by cutting. The crystals may be large enough to permit a visual inspection without the need to magnify the appearance of the BMG sample. For crystals that are smaller, a magnification device such as a microscope such as a metallurgical microscope may be used. The sampling portion can be a portion protruding out of the main BMG material or can be a region or the main body being designated as the sampling portion.

In another embodiment, the BMG sample and/or the sampling portion may be examined through a hardness test. The hardness test may be performed on a sampling portion of the BMG sample or may be performed on the main body of the material, or both. The hardness test may test the ability of the material to resist plastic deformation, or may test the ability of the material to resist scratching. In one embodiment, an indenter may be used to apply a force on the BMG sample. The amount of indentation may be measured and correlated with the indentation force to calculate hardness. The indentation may be applied in accordance with a Vickers hardness test, or any other hardness test as described below.

Another embodiment describes a process of examining a BMG sample through differential scanning calorimetry (DSC). In the DSC test, the heat needed to increase the temperature of a BMG sample and a reference material may be measured. The heat flow needed to heat both materials may be analyzed for changes in the heat flow required by the BMG sample relative to that for the reference material. For example, changes in the difference between the heat flow applied to the BMG sample and the heat flow applied to the reference material may be analyzed. A decrease in the heat flow relative to the reference material may indicate a crystallization event in the BMG sample, while an increase in the heat flow may indicate a melting event. The difference in the heat flow increase during melting and the heat flow decrease during crystallization may be used to calculate a material property, such as a percentage of crystallization, or crystallinity (in some embodiments) of the material.

One embodiment provides a method, comprising: forming a part comprising a bulk amorphous alloy, wherein the part comprises a sampling portion; determining a parameter related to the part by detecting optically on a surface of the sampling portion presence of crystals of the alloy; and evaluating the part based on the parameter.

An alternative embodiment provides a method, comprising: providing a part comprising a bulk amorphous alloy, wherein the part comprises a sampling portion; detecting optically in the sampling portion presence of crystals; determining a parameter related to the part by a result of the optical detection; measuring a hardness value for the sampling portion; and relating the hardness value to the parameter.

Another embodiment provides an apparatus configured to carried a method comprising: detecting optically in a sampling portion presence of crystals, the sampling portion being a portion of a part comprising a bulk amorphous alloy; determining a parameter related to the part by a result of the optical detection; measuring a hardness value for the sampling portion; and relating the hardness value to the parameter.

### BRIEF DESCRIPTION OF THE DRAWINGS

FIG. 1 provides a temperature-viscosity diagram of an exemplary bulk solidifying amorphous alloy.

FIG. 2 provides a schematic of a time-temperature-transformation (TTT) diagram for an exemplary bulk solidifying amorphous alloy.

FIGS. 3(a) and 3(b) provide schematic illustrations of a BMG sample with a protruding sampling portion 12 (1(a) and a BMG sample 11 with a sampling portion 12 separated from each other (1(b)).

FIG. 4 illustrates a differential scanning calorimetry (DSC) apparatus for measuring the heat flow in heating a BMG sample.

FIG. 5 illustrates an example of data obtained by a DSC technique.

### DETAILED DESCRIPTION

All publications, patents, and patent applications cited in this Specification are hereby incorporated by reference in their entirety.

The articles “a” and “an” are used herein to refer to one or to more than one (i.e., to at least one) of the grammatical object of the article. By way of example, “a polymer resin” means one polymer resin or more than one polymer resin. Any ranges cited herein are inclusive. The terms “substantially” and “about” used throughout this Specification are used to describe and account for small fluctuations. For example, they can refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

Bulk-solidifying amorphous alloys, or bulk metallic glasses (“BMG”), are a recently developed class of metallic materials. These alloys may be solidified and cooled at relatively slow rates, and they retain the amorphous, non-crystalline (i.e., glassy) state at room temperature. Amorphous alloys have many superior properties than their crystalline counterparts. However, if the cooling rate is not sufficiently high, crystals may form inside the alloy during cooling, so that the benefits of the amorphous state can be lost. For example, one challenge with the fabrication of bulk amorphous alloy parts is partial crystallization of the parts due to either slow cooling or impurities in the raw alloy material. As a high degree of amorphicity (and, conversely, a low degree of crystallinity) is desirable in BMG parts, there is a need to develop methods for casting BMG parts having controlled amount of amorphicity.

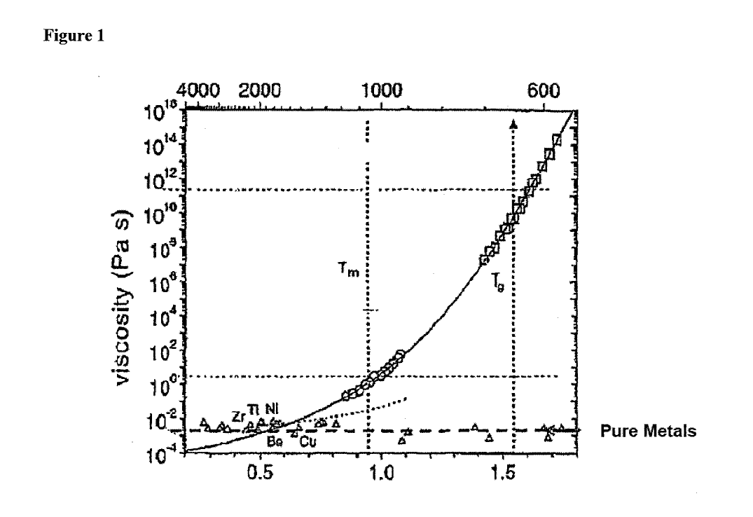

FIG. 1 (obtained from U.S. Pat. No. 7,575,040) shows a viscosity-temperature graph of an exemplary bulk solidifying amorphous alloy, from the VIT-001 series of Zr—Ti—Ni—Cu—0 Be family manufactured by Liquidmetal Technology. It should be noted that there is no clear liquid/solid transformation for a bulk solidifying amorphous metal during the formation of an amorphous solid. The molten alloy becomes more and more viscous with increasing undercooling until it approaches solid form around the glass transition temperature. Accordingly, the temperature of solidification front for bulk solidifying amorphous alloys can be around glass transition temperature, where the alloy will practically act as a solid for the purposes of pulling out the quenched amorphous sheet product.

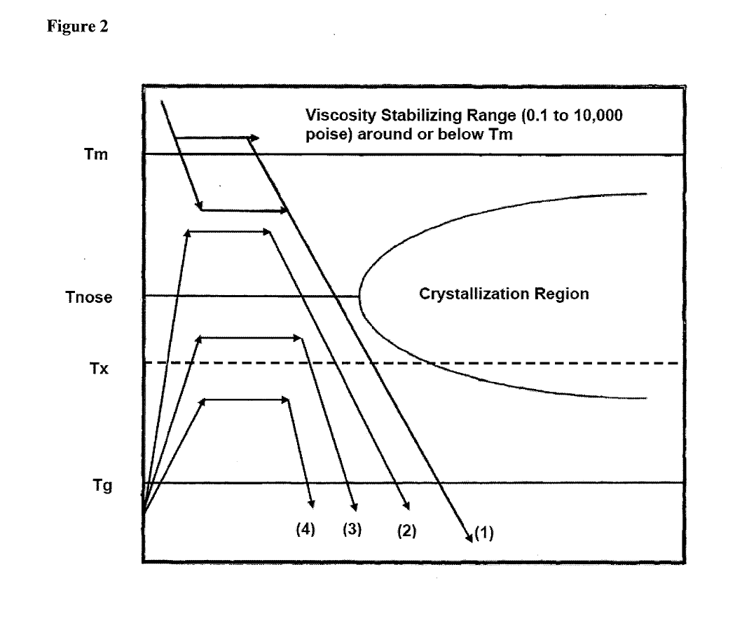

FIG. 2 (obtained from U.S. Pat. No. 7,575,040) shows the time-temperature-transformation (TTT) cooling curve of an exemplary bulk solidifying amorphous alloy, or TTT diagram. Bulk-solidifying amorphous metals do not experience a liquid/solid crystallization transformation upon cooling, as with conventional metals. Instead, the highly fluid, non crystalline form of the metal found at high temperatures (near a “melting temperature” Tm) becomes more viscous as the temperature is reduced (near to the glass transition temperature Tg), eventually taking on the outward physical properties of a conventional solid.

Even though there is no liquid/crystallization transformation for a bulk solidifying amorphous metal, a “melting temperature” Tm may be defined as the thermodynamic liquidus temperature of the corresponding crystalline phase. Under this regime, the viscosity of bulk-solidifying amorphous alloys at the melting temperature could lie in the range of about 0.1 poise to about 10,000 poise, and even sometimes under 0.01 poise. A lower viscosity at the “melting temperature” would provide faster and complete filling of intricate portions of the shell/mold with a bulk solidifying amorphous metal for forming the BMG parts. Furthermore, the cooling rate of the molten metal to form a BMG part has to such that the time-temperature profile during cooling does not traverse through the nose-shaped region bounding the crystallized region in the TTT diagram of FIG. 2. In FIG. 2, Tnose is the critical crystallization temperature Tx where crystallization is most rapid and occurs in the shortest time scale.

The supercooled liquid region, the temperature region between Tg and Tx is a manifestation of the extraordinary stability against crystallization of bulk solidification alloys. In this temperature region the bulk solidifying alloy can exist as a high viscous liquid. The viscosity of the bulk solidifying alloy in the supercooled liquid region can vary between 10¹² Pa s at the glass transition temperature down to 10⁵ Pa s at the crystallization temperature, the high temperature limit of the supercooled liquid region. Liquids with such viscosities can undergo substantial plastic strain under an applied pressure. The embodiments herein make use of the large plastic formability in the supercooled liquid region as a forming and separating method.

One needs to clarify something about Tx. Technically, the nose-shaped curve shown in the TTT diagram describes Tx as a function of temperature and time. Thus, regardless of the trajectory that one takes while heating or cooling a metal alloy, when one hits the TTT curve, one has reached Tx. In FIG. 2, Tx is shown as a dashed line as Tx can vary from close to Tm to close to Tg.

The schematic TTT diagram of FIG. 2 shows processing methods of die casting from at or above Tm to below Tg without the time-temperature trajectory (shown as (1) as an example trajectory) hitting the TTT curve. During die casting, the forming takes place substantially simultaneously with fast cooling to avoid the trajectory hitting the TTT curve. The processing methods for superplastic forming (SPF) from at or below Tg to below Tm without the time-temperature trajectory (shown as (2), (3) and (4) as example trajectories) hitting the TTT curve. In SPF, the amorphous BMG is reheated into the supercooled liquid region where the available processing window could be much larger than die casting, resulting in better controllability of the process. The SPF process does not require fast cooling to avoid crystallization during cooling. Also, as shown by example trajectories (2), (3) and (4), the SPF can be carried out with the highest temperature during SPF being above Tnose or below Tnose, up to about Tm. If one heats up a piece of amorphous alloy but manages to avoid hitting the TTT curve, you have heated “between Tg and Tm”, but one would have not reached Tx.

Typical differential scanning calorimeter (DSC) heating curves of bulk-solidifying amorphous alloys taken at a heating rate of 20 C/min describe, for the most part, a particular trajectory across the TTT data where one would likely see a Tg at a certain temperature, a Tx when the DSC heating ramp crosses the TTT crystallization onset, and eventually melting peaks when the same trajectory crosses the temperature range for melting. If one heats a bulk-solidifying amorphous alloy at a rapid heating rate as shown by the ramp up portion of trajectories (2), (3) and (4) in FIG. 2, then one could avoid the TTT curve entirely, and the DSC data would show a glass transition but no Tx upon heating. Another way to think about it is trajectories (2), (3) and (4) can fall anywhere in temperature between the nose of the TTT curve (and even above it) and the Tg line, as long as it does not hit the crystallization curve. That just means that the horizontal plateau in trajectories might get much shorter as one increases the processing temperature.

### Phase

The term “phase” herein can refer to one that can be found in a thermodynamic phase diagram. A phase is a region of space (e.g., a thermodynamic system) throughout which all physical properties of a material are essentially uniform. Examples of physical properties include density, index of refraction, chemical composition and lattice periodicity. A simple description of a phase is a region of material that is chemically uniform, physically distinct, and/or mechanically separable. For example, in a system consisting of ice and water in a glass jar, the ice cubes are one phase, the water is a second phase, and the humid air over the water is a third phase. The glass of the jar is another separate phase. A phase can refer to a solid solution, which can be a binary, tertiary, quaternary, or more, solution, or a compound, such as an intermetallic compound. As another example, an amorphous phase is distinct from a crystalline phase.

### Metal, Transition Metal, and Non-Metal

The term “metal” refers to an electropositive chemical element. The term “element” in this Specification refers generally to an element that can be found in a Periodic Table. Physically, a metal atom in the ground state contains a partially filled band with an empty state close to an occupied state. The term “transition metal” is any of the metallic elements within Groups 3 to 12 in the Periodic Table that have an incomplete inner electron shell and that serve as transitional links between the most and the least electropositive in a series of elements. Transition metals are characterized by multiple valences, colored compounds, and the ability to form stable complex ions. The term “nonmetal” refers to a chemical element that does not have the capacity to lose electrons and form a positive ion.

Depending on the application, any suitable nonmetal elements, or their combinations, can be used. The alloy (or “alloy composition”) can comprise multiple nonmetal elements, such as at least two, at least three, at least four, or more, nonmetal elements. A nonmetal element can be any element that is found in Groups 13-17 in the Periodic Table. For example, a nonmetal element can be any one of F, Cl, Br, I, At, O, S, Se, Te, Po, N, P, As, Sb, Bi, C, Si, Ge, Sn, Pb, and B. Occasionally, a nonmetal element can also refer to certain metalloids (e.g., B, Si, Ge, As, Sb, Te, and Po) in Groups 13-17. In one embodiment, the nonmetal elements can include B, Si, C, P, or combinations thereof. Accordingly, for example, the alloy can comprise a boride, a carbide, or both.

A transition metal element can be any of scandium, titanium, vanadium, chromium, manganese, iron, cobalt, nickel, copper, zinc, yttrium, zirconium, niobium, molybdenum, technetium, ruthenium, rhodium, palladium, silver, cadmium, hafnium, tantalum, tungsten, rhenium, osmium, iridium, platinum, gold, mercury, rutherfordium, dubnium, seaborgium, bohrium, hassium, meitnerium, ununnilium, unununium, and ununbium. In one embodiment, a BMG containing a transition metal element can have at least one of Sc, Y, La, Ac, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, and Hg. Depending on the application, any suitable transitional metal elements, or their combinations, can be used. The alloy composition can comprise multiple transitional metal elements, such as at least two, at least three, at least four, or more, transitional metal elements.

The presently described alloy or alloy “sample” or “specimen” alloy can have any shape or size. For example, the alloy can have a shape of a particulate, which can have a shape such as spherical, ellipsoid, wire-like, rod-like, sheet-like, flake-like, or an irregular shape. The particulate can have any size. For example, it can have an average diameter of between about 1 micron and about 100 microns, such as between about 5 microns and about 80 microns, such as between about 10 microns and about 60 microns, such as between about 15 microns and about 50 microns, such as between about 15 microns and about 45 microns, such as between about 20 microns and about 40 microns, such as between about 25 microns and about 35 microns. For example, in one embodiment, the average diameter of the particulate is between about 25 microns and about 44 microns. In some embodiments, smaller particulates, such as those in the nanometer range, or larger particulates, such as those bigger than 100 microns, can be used.

The alloy sample or specimen can also be of a much larger dimension. For example, it can be a bulk structural component, such as an ingot, housing/casing of an electronic device or even a portion of a structural component that has dimensions in the millimeter, centimeter, or meter range.

### Solid Solution

The term “solid solution” refers to a solid form of a solution. The term “solution” refers to a mixture of two or more substances, which may be solids, liquids, gases, or a combination of these. The mixture can be homogeneous or heterogeneous. The term “mixture” is a composition of two or more substances that are combined with each other and are generally capable of being separated. Generally, the two or more substances are not chemically combined with each other.

### Alloy

In some embodiments, the alloy composition described herein can be fully alloyed. In one embodiment, an “alloy” refers to a homogeneous mixture or solid solution of two or more metals, the atoms of one replacing or occupying interstitial positions between the atoms of the other; for example, brass is an alloy of zinc and copper. An alloy, in contrast to a composite, can refer to a partial or complete solid solution of one or more elements in a metal matrix, such as one or more compounds in a metallic matrix. The term alloy herein can refer to both a complete solid solution alloy that can give single solid phase microstructure and a partial solution that can give two or more phases. An alloy composition described herein can refer to one comprising an alloy or one comprising an alloy-containing composite.

Thus, a fully alloyed alloy can have a homogenous distribution of the constituents, be it a solid solution phase, a compound phase, or both. The term “fully alloyed” used herein can account for minor variations within the error tolerance. For example, it can refer to at least 90% alloyed, such as at least 95% alloyed, such as at least 99% alloyed, such as at least 99.5% alloyed, such as at least 99.9% alloyed. The percentage herein can refer to either volume percent or weight percentage, depending on the context. These percentages can be balanced by impurities, which can be in terms of composition or phases that are not a part of the alloy.

### Amorphous or Non-Crystalline Solid

An “amorphous” or “non-crystalline solid” is a solid that lacks lattice periodicity, which is characteristic of a crystal. As used herein, an “amorphous solid” includes “glass” which is an amorphous solid that softens and transforms into a liquid-like state upon heating through the glass transition. Generally, amorphous materials lack the long-range order characteristic of a crystal, though they can possess some short-range order at the atomic length scale due to the nature of chemical bonding. The distinction between amorphous solids and crystalline solids can be made based on lattice periodicity as determined by structural characterization techniques such as x-ray diffraction and transmission electron microscopy.

The terms “order” and “disorder” designate the presence or absence of some symmetry or correlation in a many-particle system. The terms “long-range order” and “short-range order” distinguish order in materials based on length scales.

The strictest form of order in a solid is lattice periodicity: a certain pattern (the arrangement of atoms in a unit cell) is repeated again and again to form a translationally invariant tiling of space. This is the defining property of a crystal. Possible symmetries have been classified in 14 Bravais lattices and 230 space groups.

Lattice periodicity implies long-range order. If only one unit cell is known, then by virtue of the translational symmetry it is possible to accurately predict all atomic positions at arbitrary distances. The converse is generally true, except, for example, in quasi-crystals that have perfectly deterministic tilings but do not possess lattice periodicity.

Long-range order characterizes physical systems in which remote portions of the same sample exhibit correlated behavior. This can be expressed as a correlation function, namely the spin-spin correlation function: G(x, x′)=<s(x), s(x′)>.

In the above function, s is the spin quantum number and x is the distance function within the particular system. This function is equal to unity when x=x′ and decreases as the distance |x−x′| increases. Typically, it decays exponentially to zero at large distances, and the system is considered to be disordered. If, however, the correlation function decays to a constant value at large |x−x′|, then the system can be said to possess long-range order. If it decays to zero as a power of the distance, then it can be called quasi-long-range order. Note that what constitutes a large value of |x−x′| is relative.

A system can be said to present quenched disorder when some parameters defining its behavior are random variables that do not evolve with time (i.e., they are quenched or frozen)—e.g., spin glasses. It is opposite to annealed disorder, where the random variables are allowed to evolve themselves. Embodiments herein include systems comprising quenched disorder.

The alloy described herein can be crystalline, partially crystalline, amorphous, or substantially amorphous. For example, the alloy sample/specimen can include at least some crystallinity, with grains/crystals having sizes in the nanometer and/or micrometer ranges. Alternatively, the alloy can be substantially amorphous, such as fully amorphous. In one embodiment, the alloy composition is at least substantially not amorphous, such as being substantially crystalline, such as being entirely crystalline.

In one embodiment, the presence of a crystal or a plurality of crystals in an otherwise amorphous alloy can be construed as a “crystalline phase” therein. The degree of crystallinity (or “crystallinity” for short in some embodiments) of an alloy can refer to the amount of the crystalline phase present in the alloy. The degree can refer to, for example, a fraction of crystals present in the alloy. The fraction can refer to volume fraction or weight fraction, depending on the context. A measure of how “amorphous” an amorphous alloy is can be amorphicity. Amorphicity can be measured in terms of a degree of crystallinity. For example, in one embodiment, an alloy having a low degree of crystallinity can be said to have a high degree of amorphicity. In one embodiment, for example, an alloy having 60 vol % crystalline phase can have a 40 vol % amorphous phase.

### Amorphous Alloy or Amorphous Metal

An “amorphous alloy” is an alloy having an amorphous content of more than 50% by volume, preferably more than 90% by volume of amorphous content, more preferably more than 95% by volume of amorphous content, and most preferably more than 99% to almost 100% by volume of amorphous content. Note that, as described above, an alloy high in amorphicity is equivalently low in degree of crystallinity. An “amorphous metal” is an amorphous metal material with a disordered atomic-scale structure. In contrast to most metals, which are crystalline and therefore have a highly ordered arrangement of atoms, amorphous alloys are non-crystalline. Materials in which such a disordered structure is produced directly from the liquid state during cooling are sometimes referred to as “glasses.” Accordingly, amorphous metals are commonly referred to as “metallic glasses” or “glassy metals.” In one embodiment, a bulk metallic glass (“BMG”) can refer to an alloy, of which the microstructure is at least partially amorphous. However, there are several ways besides extremely rapid cooling to produce amorphous metals, including physical vapor deposition, solid-state reaction, ion irradiation, melt spinning, and mechanical alloying. Amorphous alloys can be a single class of materials, regardless of how they are prepared.

Amorphous metals can be produced through a variety of quick-cooling methods. For instance, amorphous metals can be produced by sputtering molten metal onto a spinning metal disk. The rapid cooling, on the order of millions of degrees a second, can be too fast for crystals to form, and the material is thus “locked in” a glassy state. Also, amorphous metals/alloys can be produced with critical cooling rates low enough to allow formation of amorphous structures in thick layers—e.g., bulk metallic glasses.

The terms “bulk metallic glass” (“BMG”), bulk amorphous alloy (“BAA”), and bulk solidifying amorphous alloy are used interchangeably herein. They refer to amorphous alloys having the smallest dimension at least in the millimeter range. For example, the dimension can be at least about 0.5 mm, such as at least about 1 mm, such as at least about 2 mm, such as at least about 4 mm, such as at least about 5 mm, such as at least about 6 mm, such as at least about 8 mm, such as at least about 10 mm, such as at least about 12 mm. Depending on the geometry, the dimension can refer to the diameter, radius, thickness, width, length, etc. A BMG can also be a metallic glass having at least one dimension in the centimeter range, such as at least about 1.0 cm, such as at least about 2.0 cm, such as at least about 5.0 cm, such as at least about 10.0 cm. In some embodiments, a BMG can have at least one dimension at least in the meter range. A BMG can take any of the shapes or forms described above, as related to a metallic glass. Accordingly, a BMG described herein in some embodiments can be different from a thin film made by a conventional deposition technique in one important aspect—the former can be of a much larger dimension than the latter.

Amorphous metals can be an alloy rather than a pure metal. The alloys may contain atoms of significantly different sizes, leading to low free volume (and therefore having viscosity up to orders of magnitude higher than other metals and alloys) in a molten state. The viscosity prevents the atoms from moving enough to form an ordered lattice. The material structure may result in low shrinkage during cooling and resistance to plastic deformation. The absence of grain boundaries, the weak spots of crystalline materials in some cases, may, for example, lead to better resistance to wear and corrosion. In one embodiment, amorphous metals, while technically glasses, may also be much tougher and less brittle than oxide glasses and ceramics.

Thermal conductivity of amorphous materials may be lower than that of their crystalline counterparts. To achieve formation of an amorphous structure even during slower cooling, the alloy may be made of three or more components, leading to complex crystal units with higher potential energy and lower probability of formation. The formation of amorphous alloy can depend on several factors: the composition of the components of the alloy; the atomic radius of the components (preferably with a significant difference of over 12% to achieve high packing density and low free volume); and the negative heat of mixing the combination of components, inhibiting crystal nucleation and prolonging the time the molten metal stays in a supercooled state. However, as the formation of an amorphous alloy is based on many different variables, it can be difficult to make a prior determination of whether an alloy composition would form an amorphous alloy.

Amorphous alloys, for example, of boron, silicon, phosphorus, and other glass formers with magnetic metals (iron, cobalt, nickel) may be magnetic, with low coercivity and high electrical resistance. The high resistance leads to low losses by eddy currents when subjected to alternating magnetic fields, a property useful, for example, as transformer magnetic cores.

Amorphous alloys may have a variety of potentially useful properties. In particular, they tend to be stronger than crystalline alloys of similar chemical composition, and they can sustain larger reversible (“elastic”) deformations than crystalline alloys. Amorphous metals derive their strength directly from their non-crystalline structure, which can have none of the defects (such as dislocations) that limit the strength of crystalline alloys. For example, one modern amorphous metal, known as Vitreloy™, has a tensile strength that is almost twice that of high-grade titanium. In some embodiments, metallic glasses at room temperature are not ductile and tend to fail suddenly when loaded in tension, which limits the material applicability in reliability-critical applications, as the impending failure is not evident. Therefore, to overcome this challenge, metal matrix composite materials having a metallic glass matrix containing dendritic particles or fibers of a ductile crystalline metal can be used. Alternatively, a BMG low in element(s) that tend to cause embitterment (e.g., Ni) can be used. For example, a Ni-free BMG can be used to improve the ductility of the BMG.

Another useful property of bulk amorphous alloys is that they can be true glasses; in other words, they can soften and flow upon heating. This can allow for easy processing, such as by injection molding, in much the same way as polymers. As a result, amorphous alloys can be used for making sports equipment, medical devices, electronic components and equipment, and thin films. Thin films of amorphous metals can be deposited as protective coatings via a high velocity oxygen fuel technique.

A material can have an amorphous phase, a crystalline phase, or both. The amorphous and crystalline phases can have the same chemical composition and differ only in the microstructure—i.e., one amorphous and the other crystalline. Microstructure in one embodiment refers to the structure of a material as revealed by a microscope at 25× magnification or higher. Alternatively, the two phases can have different chemical compositions and microstructures. For example, a composition can be partially amorphous, substantially amorphous, or completely amorphous.

As described above, the degree of amorphicity (and conversely the degree of crystallinity) can be measured by fraction of crystals present in the alloy. The degree can refer to volume fraction of weight fraction of the crystalline phase present in the alloy. A partially amorphous composition can refer to a composition of at least about 5 vol % of which is of an amorphous phase, such as at least about 10 vol %, such as at least about 20 vol %, such as at least about 40 vol %, such as at least about 60 vol %, such as at least about 80 vol %, such as at least about 90 vol %. The terms “substantially” and “about” have been defined elsewhere in this application. Accordingly, a composition that is at least substantially amorphous can refer to one of which at least about 90 vol % is amorphous, such as at least about 95 vol %, such as at least about 98 vol %, such as at least about 99 vol %, such as at least about 99.5 vol %, such as at least about 99.8 vol %, such as at least about 99.9 vol %. In one embodiment, a substantially amorphous composition can have some incidental, insignificant amount of crystalline phase present therein.

In one embodiment, an amorphous alloy composition can be homogeneous with respect to the amorphous phase. A substance that is uniform in composition is homogeneous. This is in contrast to a substance that is heterogeneous. The term “composition” refers to the chemical composition and/or microstructure in the substance. A substance is homogeneous when a volume of the substance is divided in half and both halves have substantially the same composition. For example, a particulate suspension is homogeneous when a volume of the particulate suspension is divided in half and both halves have substantially the same volume of particles. However, it might be possible to see the individual particles under a microscope. Another example of a homogeneous substance is air where different ingredients therein are equally suspended, though the particles, gases and liquids in air can be analyzed separately or separated from air.

A composition that is homogeneous with respect to an amorphous alloy can refer to one having an amorphous phase substantially uniformly distributed throughout its microstructure. In other words, the composition macroscopically comprises a substantially uniformly distributed amorphous alloy throughout the composition. In an alternative embodiment, the composition can be of a composite, having an amorphous phase having therein a non-amorphous phase. The non-amorphous phase can be a crystal or a plurality of crystals. The crystals can be in the form of particulates of any shape, such as spherical, ellipsoid, wire-like, rod-like, sheet-like, flake-like, or an irregular shape. In one embodiment, it can have a dendritic form. For example, an at least partially amorphous composite composition can have a crystalline phase in the shape of dendrites dispersed in an amorphous phase matrix; the dispersion can be uniform or non-uniform, and the amorphous phase and the crystalline phase can have the same or a different chemical composition. In one embodiment, they have substantially the same chemical composition. In another embodiment, the crystalline phase can be more ductile than the BMG phase.

The methods described herein can be applicable to any type of amorphous alloy. Similarly, the amorphous alloy described herein as a constituent of a composition or article can be of any type. The amorphous alloy can comprise the element Zr, Hf, Ti, Cu, Ni, Pt, Pd, Fe, Mg, Au, La, Ag, Al, Mo, Nb, Be, or combinations thereof Namely, the alloy can include any combination of these elements in its chemical formula or chemical composition: The elements can be present at different weight or volume percentages. For example, an iron “based” alloy can refer to an alloy having a non-insignificant weight percentage of iron present therein, the weight percent can be, for example, at least about 20 wt %, such as at least about 40 wt %, such as at least about 50 wt %, such as at least about 60 wt %, such as at least about 80 wt %. Alternatively, in one embodiment, the above-described percentages can be volume percentages, instead of weight percentages. Accordingly, an amorphous alloy can be zirconium-based, titanium-based, platinum-based, palladium-based, gold-based, silver-based, copper-based, iron-based, nickel-based, aluminum-based, molybdenum-based, and the like. The alloy can also be free of any of the aforementioned elements to suit a particular purpose. For example, in some embodiments, the alloy, or the composition including the alloy, can be substantially free of nickel, aluminum, titanium, beryllium, or combinations thereof. In one embodiment, the alloy or the composite is completely free of nickel, aluminum, titanium, beryllium, or combinations thereof.

For example, the amorphous alloy can have the formula (Zr, Ti)ₐ(Ni, Cu, Fe)_{b}(Be, Al, Si, B)_{c}, wherein a, b, and c each represents a weight or atomic percentage. In one embodiment, a is in the range of from 30 to 75, b is in the range of from 5 to 60, and c is in the range of from 0 to 50 in atomic percentages. Alternatively, the amorphous alloy can have the formula (Zr, Ti)ₐ(Ni, Cu)_{b}(Be)_{c}, wherein a, b, and c each represents a weight or atomic percentage. In one embodiment, a is in the range of from 40 to 75, b is in the range of from 5 to 50, and c is in the range of from 5 to 50 in atomic percentages. The alloy can also have the formula (Zr, Ti)ₐ(Ni, Cu)_{b}(Be)_{c}, wherein a, b, and c each represents a weight or atomic percentage. In one embodiment, a is in the range of from 45 to 65, b is in the range of from 7.5 to 35, and c is in the range of from 10 to 37.5 in atomic percentages. Alternatively, the alloy can have the formula (Zr)ₐ(Nb, Ti)_{b}(Ni, Cu)_{c}(Al)_{d}, wherein a, b, c, and d each represents a weight or atomic percentage. In one embodiment, a is in the range of from 45 to 65, b is in the range of from 0 to 10, c is in the range of from 20 to 40 and d is in the range of from 7.5 to 15 in atomic percentages. One exemplary embodiment of the aforedescribed alloy system is a Zr—Ti—Ni—Cu—Be based amorphous alloy under the trade name Vitreloy™, such as Vitreloy-1 and Vitreloy-101, as fabricated by Liquidmetal Technologies, CA, USA. Some examples of amorphous alloys of the different systems are provided in Table 1 and Table 2.

TABLE 1
Exemplary amorphous alloy compositions (atomic %)

| Alloy | Atm % | Atm % | Atm % | Atm % | Atm % | Atm % |
|---|---|---|---|---|---|---|
| 1 | Zr | Ti | Cu | Ni | Be | |
| | 41.20% | 13.80% | 12.50% | 10.00% | 22.50% | |
| 2 | Zr | Ti | Cu | Ni | Be | |
| | 44.00% | 11.00% | 10.00% | 10.00% | 25.00% | |
| 3 | Zr | Ti | Cu | Ni | Nb | Be |
| | 56.25% | 11.25% | 6.88% | 5.63% | 7.50% | 12.50% |
| 4 | Zr | Ti | Cu | Ni | Al | Be |
| | 64.75% | 5.60% | 14.90% | 11.15% | 2.60% | 1.00% |
| 5 | Zr | Ti | Cu | Ni | Al | |
| | 52.50% | 5.00% | 17.90% | 14.60% | 10.00% | |
| 6 | Zr | Nb | Cu | Ni | Al | |
| | 57.00% | 5.00% | 15.40% | 12.60% | 10.00% | |
| 7 | Zr | Cu | Ni | Al | | |
| | 50.75% | 36.23% | 4.03% | 9.00% | | |
| 8 | Zr | Ti | Cu | Ni | Be | |
| | 46.75% | 8.25% | 7.50% | 10.00% | 27.50% | |
| 9 | Zr | Ti | Ni | Be | | |
| | 21.67% | 43.33% | 7.50% | 27.50% | | |
| 10 | Zr | Ti | Cu | Be | | |
| | 35.00% | 30.00% | 7.50% | 27.50% | | |
| 11 | Zr | Ti | Co | Be | | |
| | 35.00% | 30.00% | 6.00% | 29.00% | | |
| 12 | Zr | Ti | Fe | Be | | |
| | 35.00% | 30.00% | 2.00% | 33.00% | | |
| 13 | Au | Ag | Pd | Cu | Si | |
| | 49.00% | 5.50% | 2.30% | 26.90% | 16.30% | |
| 14 | Au | Ag | Pd | Cu | Si | |
| | 50.90% | 3.00% | 2.30% | 27.80% | 16.00% | |
| 15 | Pt | Cu | Ni | P | | |
| | 57.50% | 14.70% | 5.30% | 22.50% | | |
| 16 | Zr | Ti | Nb | Cu | Be | |
| | 36.60% | 31.40% | 7.00% | 5.90% | 19.10% | |
| 17 | Zr | Ti | Nb | Cu | Be | |
| | 38.30% | 32.90% | 7.30% | 6.20% | 15.30% | |
| 18 | Zr | Ti | Nb | Cu | Be | |
| | 39.60% | 33.90% | 7.60% | 6.40% | 12.50% | |
| 19 | Cu | Ti | Zr | Ni | | |
| | 47.00% | 34.00% | 11.00% | 8.00% | | |
| 20 | Zr | Co | Al | | | |
| | 55.00% | 25.00% | 20.00% | | | |

TABLE 2
Additional exemplary amorphous alloy compositions

| Alloy | Atm % | Atm % | Atm % | Atm % | Atm % | Atm % | Atm % | Atm % |
|---|---|---|---|---|---|---|---|---|
| 1 | Fe | Mo | Ni | Cr | P | C | B | |
| | 68.00% | 5.00% | 5.00% | 2.00% | 12.50% | 5.00% | 2.50% | |
| 2 | Fe | Mo | Ni | Cr | P | C | B | Si |
| | 68.00% | 5.00% | 5.00% | 2.00% | 11.00% | 5.00% | 2.50% | 1.50% |
| 3 | Pd | Cu | Co | P | | | | |
| | 44.48% | 32.35% | 4.05% | 19.11% | | | | |
| 4 | Pd | Ag | Si | P | | | | |
| | 77.50% | 6.00% | 9.00% | 7.50% | | | | |
| 5 | Pd | Ag | Si | P | Ge | | | |
| | 79.00% | 3.50% | 9.50% | 6.00% | 2.00% | | | |
| 5 | Pt | Cu | Ag | P | B | Si | | |
| | 74.70% | 1.50% | 0.30% | 18.0% | 4.00% | 1.50% | | |

The amorphous alloys can also be ferrous alloys, such as (Fe, Ni, Co) based alloys. Examples of such compositions are disclosed in U.S. Pat. Nos. 6,325,868; 5,288,344; 5,368,659; 5,618,359; and 5,735,975, Inoue et al., Appl. Phys. Lett., Volume 71, p 464 (1997), Shen et al., Mater. Trans., JIM, Volume 42, p 2136 (2001), and Japanese Patent Application No. 200126277 (Pub. No. 2001303218 A). One exemplary composition is Fe₇₂Al₅Ga₂P₁₁C₆B₄. Another example is Fe₇₂Al₇Zr_{1.0}Mo₅W₂B₁₅. Another iron-based alloy system that can be used in the coating herein is disclosed in U.S. Patent Application Publication No. 2010/0084052, wherein the amorphous metal contains, for example, manganese (1 to 3 atomic %), yttrium (0.1 to 10 atomic %), and silicon (0.3 to 3.1 atomic %) in the range of composition given in parentheses; and that contains the following elements in the specified range of composition given in parentheses: chromium (15 to 20 atomic %), molybdenum (2 to 15 atomic %), tungsten (1 to 3 atomic %), boron (5 to 16 atomic %), carbon (3 to 16 atomic %), and the balance iron.

Other exemplary ferrous metal-based alloys include compositions such as those disclosed in U.S. Patent Application Publication Nos. 2007/0079907 and 2008/0118387. These compositions include the Fe(Mn, Co, Ni, Cu) (C, Si, B, P, Al) system, wherein the Fe content is from 60 to 75 atomic percentage, the total of (Mn, Co, Ni, Cu) is in the range of from 5 to 25 atomic percentage, and the total of (C, Si, B, P, Al) is in the range of from 8 to 20 atomic percentage, as well as the exemplary composition Fe48Cr15Mo14Y2C15B6. They also include the alloy systems described by Fe—Cr—Mo—(Y,Ln)-C—B, Co—Cr—Mo-Ln-C—B, Fe—Mn—Cr—Mo—(Y,Ln)-C—B, (Fe, Cr, Co)—(Mo,Mn)—(C,B)—Y, Fe—(Co,Ni)—(Zr,Nb,Ta)—(Mo,W)—B, Fe—(Al,Ga)—(P,C,B,Si,Ge), Fe—(Co, Cr,Mo,Ga,Sb)—P—B—C, (Fe, Co)—B—Si—Nb alloys, and Fe—(Cr—Mo)—(C,B)—Tm, where Ln denotes a lanthanide element and Tm denotes a transition metal element. Furthermore, the amorphous alloy can also be one of the exemplary compositions Fe80P12.5C5B2.5, Fe80P11C5B2.5Si1.5, Fe74.5Mo5.5P12.5C5B2.5, Fe74.5Mo5.5P11C5B2.5Si1.5, Fe70Mo5Ni5P12.5C5B2.5, Fe70Mo5Ni5P11C5B2.5 Si 1.5, Fe68Mo5Ni5Cr2P12.5C5B2.5, and Fe68Mo5Ni5Cr2P11C5B2.5Si1.5, described in U.S. Patent Application Publication No. 2010/0300148.

The amorphous alloy can also be one of the Pt- or Pd-based alloys described by U.S. Patent Application Publication Nos. 2008/0135136, 2009/0162629, and 2010/0230012. Exemplary compositions include Pd44.48Cu32.35Co4.05P19.11, Pd77.5Ag6Si9P7.5, and Pt74.7Cu1.5Ag0.3P18B4Si1.5.

The aforedescribed amorphous alloy systems can further include additional elements, such as additional transition metal elements, including Nb, Cr, V, and Co. The additional elements can be present at less than or equal to about 30 wt %, such as less than or equal to about 20 wt %, such as less than or equal to about 10 wt %, such as less than or equal to about 5 wt %. In one embodiment, the additional, optional element is at least one of cobalt, manganese, zirconium, tantalum, niobium, tungsten, yttrium, titanium, vanadium and hafnium to form carbides and further improve wear and corrosion resistance. Further optional elements may include phosphorous, germanium and arsenic, totaling up to about 2%, and preferably less than 1%, to reduce melting point. Otherwise incidental impurities should be less than about 2% and preferably 0.5%.

In some embodiments, a composition having an amorphous alloy can include a small amount of impurities. The impurity elements can be intentionally added to modify the properties of the composition, such as improving the mechanical properties (e.g., hardness, strength, fracture mechanism, etc.) and/or improving the corrosion resistance. Alternatively, the impurities can be present as inevitable, incidental impurities, such as those obtained as a byproduct of processing and manufacturing. The impurities can be less than or equal to about 10 wt %, such as about 5 wt %, such as about 2 wt %, such as about 1 wt %, such as about 0.5 wt %, such as about 0.1 wt %. In some embodiments, these percentages can be volume percentages instead of weight percentages. In one embodiment, the alloy sample/composition consists essentially of the amorphous alloy (with only a small incidental amount of impurities). In another embodiment, the composition includes the amorphous alloy (with no observable trace of impurities).

In one embodiment, the final parts exceeded the critical casting thickness of the bulk solidifying amorphous alloys.

In embodiments herein, the existence of a supercooled liquid region in which the bulk-solidifying amorphous alloy can exist as a high viscous liquid allows for superplastic forming. Large plastic deformations can be obtained. The ability to undergo large plastic deformation in the supercooled liquid region is used for the forming and/or cutting process. As oppose to solids, the liquid bulk solidifying alloy deforms locally which drastically lowers the required energy for cutting and forming. The ease of cutting and forming depends on the temperature of the alloy, the mold, and the cutting tool. As higher is the temperature, the lower is the viscosity, and consequently easier is the cutting and forming.

Embodiments herein can utilize a thermoplastic-forming process with amorphous alloys carried out between Tg and Tx, for example. Herein, Tx and Tg are determined from standard DSC measurements at typical heating rates (e.g. 20° C./min) as the onset of crystallization temperature and the onset of glass transition temperature.

The amorphous alloy components can have the critical casting thickness and the final part can have thickness that is thicker than the critical casting thickness. Moreover, the time and temperature of the heating and shaping operation is selected such that the elastic strain limit of the amorphous alloy could be substantially preserved to be not less than 1.0%, and preferably not being less than 1.5%. In the context of the embodiments herein, temperatures around glass transition means the forming temperatures can be below glass transition, at or around glass transition, and above glass transition temperature, but preferably at temperatures below the crystallization temperature T_{X}. The cooling step is carried out at rates similar to the heating rates at the heating step, and preferably at rates greater than the heating rates at the heating step. The cooling step is also achieved preferably while the forming and shaping loads are still maintained

### Electronic Devices

The embodiments herein can be valuable in the fabrication of electronic devices using a BMG. An electronic device herein can refer to any electronic device known in the art. For example, it can be a telephone, such as a cell phone, and a land-line phone, or any communication device, such as a smart phone, including, for example an iPhone™, and an electronic email sending/receiving device. It can be a part of a display, such as a digital display, a TV monitor, an electronic-book reader, a portable web-browser (e.g., iPad™), and a computer monitor. It can also be an entertainment device, including a portable DVD player, conventional DVD player, Blue-Ray disk player, video game console, music player, such as a portable music player (e.g., iPod™), etc. It can also be a part of a device that provides control, such as controlling the streaming of images, videos, sounds (e.g., Apple TV™), or it can be a remote control for an electronic device. It can be a part of a computer or its accessories, such as the hard drive tower housing or casing, laptop housing, laptop keyboard, laptop track pad, desktop keyboard, mouse, and speaker. The article can also be applied to a device such as a watch or a clock.

### Optical Measurement

One embodiment described herein provides a method, comprising: forming a part comprising an alloy that is at least partially amorphous, wherein the part comprises a sampling portion; determining a parameter related to the part by detecting optically on a surface of the sampling portion presence of crystals of the alloy; and evaluating the part based on the parameter. In one embodiment, the alloy can be a bulk amorphous alloy, or BMG.

The part can be a structural component of a larger article, such as a device, such as an electronic device, which is discussed in greater detail below. The part, including the sampling portion, can consist essentially of a BMG. Alternatively, the part can consist of a BMG. In another embodiment, the part can comprise a mixture of an amorphous phase alloy and a crystalline phase alloy. They two alloys can have similar composition, or the same compositions, and differ only in the phase. In the embodiment where both an amorphous and a crystalline phase are present, detection techniques can be applied to identify the presence of each of the phases. In one embodiment, the presence of each of the phases can be further quantified.

The part may be optically inspected to detect the presence of crystals in a sampling portion of the part. The sampling portion may be an elongated gate that protrudes from the main portion of the BMG sample. In one embodiment, the sampling portion can be an excess of the part when the part is made, such as a left-over or extra from injection molding. Alternatively, the sampling portion can be a non-excess portion of the part and instead be a region or portion on the main BMG sample designated as a sampling portion to be inspected and/or tested. In the embodiment wherein the sampling portion is in the form of a gate, the gate can have any desirable geometry. For example, the gate can have a certain uniform cross-section with a dimension selected such that statistically at least a certain percent, e.g., 95%, of the alloy feedstock would generate a fully amorphous material throughout the thickness. In one embodiment, the part (and/or the sampling portion) can have a geometry that has at least one dimension that is greater or equal to the critical thickness of the amorphous alloy.

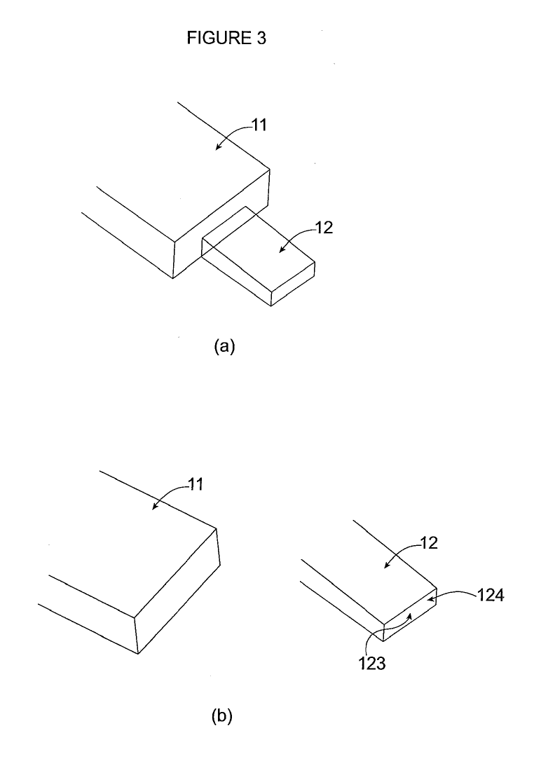

The gate may be separated from the main portion of the part to serve as a sample for testing. The separation can involve any types of suitable severing techniques as aforedescribed. For example, it can involve sawing, cutting, shearing, etc. In one embodiment, the sampling portion can include a region or cross section of the amorphous alloy material that is subjected to the least optimal cooling rate—i.e., a region where a crystalline phase is likely to be present. By designating such a region to be the sampling portion or the region to be inspected in the sampling portion, the part can be inspected for presence of crystals. For example, the sampling portion can be a gate that is formed as a protrusion from the center of a rod- or bar-shaped material comprising an amorphous alloy, such as a BMG, as a result of a forming process, such as injection molding. In one embodiment, because of the geometry, the enter of the gate, shown as point 123 in the sampling portion 12 in FIG. 3(b). The gate may contain properties of the center of the BMG sample, which may have cooled at the lowest rate.

The part or just the sampling portion, or both may be optically inspected to determine the presence of crystallization at that region. Optical inspection can be useful as to identify the presence of crystals by direct visual observation. Optical inspection may be carried out with a microscope, such as an optical microscope, such as a metallurgical microscope. The inspection can take place at any location in the sampling portion (or the main body of the BMG sample as well). For example, it can take place in a center region of the surface, or it can take place close to an edge of the surface, see points 123 and 124, respectively.

The part can be inspected as is, or it can be processed first before being the inspection. For example, it can be polished to enhance the visibility of crystalline features under the microscope. Polishing techniques are known, and any of the known techniques can be used. The microscope may use a plain glass reflector that directs light to the part. The microscope may be able to achieve a magnification on a range of 50 × to 1000×. The magnifying power can be higher or lower, depending on the microscope used and the type of sample to be inspected. Depending on the sample and the type of microscope used, different sources of light may be applied for the optical inspection. For example, bright-field illumination may be applied for BMG containing Fe constituents, while polarized light may be applied for BMG containing beryllium, cadmium, magnesium, titanium, zinc, or zirconium. Also, bright field contrast or cathode luminescence techniques can be used for imaging the surface of the BMG. Other embodiments may use a general optical microscope, an electron microscope, an atomic force microscope, scanning electron microscope, a scan tunneling microscope, or any other type of microscope capable of magnifying an image.

### Hardness Measurement

Presence of crystals may also be identified via hardness measurement, or a combination of both optical inspection and hardness measurement. As aforementioned, an amorphous alloy has different mechanical properties, including hardness value, from its crystalline counterpart. For example, an amorphous alloy can have a higher hardness value than its crystalline counterpart (of the same composition). Thus, by measuring the hardness value and comparing to a known/standard value, one would be able to distinguish a crystalline alloy from an amorphous alloy. In one embodiment, the technique can be used to identify the possible presence of crystals in structural part made of an alloy (or metal), as the hardness measurement can be localized measurement, such as at either point 123 or 124 (or both) in FIG. 3(b).

A BMG material may have a hardness value in the range from a few MPa's to several GPa's. Hardness measurement can be used to identify the presence of crystal in an otherwise amorphous alloy sample because an amorphous alloy and a crystalline alloy of the same chemical composition can have different hardness values. Thus, by comparing the hardness value of a sample of unknown crystallinity against that of a standard (e.g., fully amorphous and/or fully crystalline alloy of the same composition), the presence of crystals may be deduced. For example, of the hardness value of the sample of unknown crystallinity is lower than that of a fully amorphous standard, then it may be deduced that the sample is not fully amorphous, as it is known that amorphous alloys can have higher hardness than their crystalline counterparts. Furthermore, by establishing the standard at different crystallinity (e.g., 25%, 50%, 75%, etc.) The one may even be able to predict the degree of crystallinity of the unknown sample by repeating the comparison at several degrees of crystallinity from different standard samples.

Hardness testing may test the ability of the material to resist plastic deformation, resistance to being scratched by another substance, stiffness, or another test testing the hardness of the material. Thus, by extension the hardness value obtained can be used to derive other material properties, such as Young's modulus, yield strength, wear resistance, etc. The hardness can be measured by, for example, indentation, which can be carried out by, for example, Rockwell test, Brinell test, Vickers test, Knoop test, Shore test, or combinations thereof. The hardness can also be measured by any techniques readily known. The indentation can be micro-indentation or nano-indentation, or it can be performed at a larger or smaller length scale depending on the situation. The amount of force may be applied for a time ranging from a few microseconds to a few minutes. The level of indentation force may vary from a few nano-Newtons to a few thousand Newtons. The amount of indentation achieved (e.g., indentation area) may range from a few nanometers to a few millimeters. Hardness may be evaluated based on the indentation depth, diameter of the indentation, the indentation force, or combinations thereof. In some embodiments, the indenter used in hardness measurement can be used further to perform other types mechanical tests, such as scratching test to measurement wear resistance. For example, the scratching test can be Mohs test, Barcol test, or any other test that can examine the material's ability to resist scratching.

The hardness measurement and optical inspection described herein can be used alone or in combination. For example, one embodiment herein provides a method comprising: providing a part comprising a bulk amorphous alloy, wherein the part comprises a sampling portion; detecting optically in the sampling portion presence of crystals; determining a parameter related to the part by a result of the optical detection; measuring a hardness value for the sampling portion; and relating the hardness value to the parameter. In one embodiment, the hardness value and the parameter can be used alone or in combination to serve as quality control parameter for an alloy (or alloy part) fabrication process.

### DSC

The degree of crystallinity can be correlated and determined based on the hardness and/or optical inspection (by a microscope) as described above. In one embodiment, by delineating the correlation between different degrees of crystallinity with hardness values, one will be able to deduce the degree of crystallinity of an unknown sample based on a hardness measurement results.

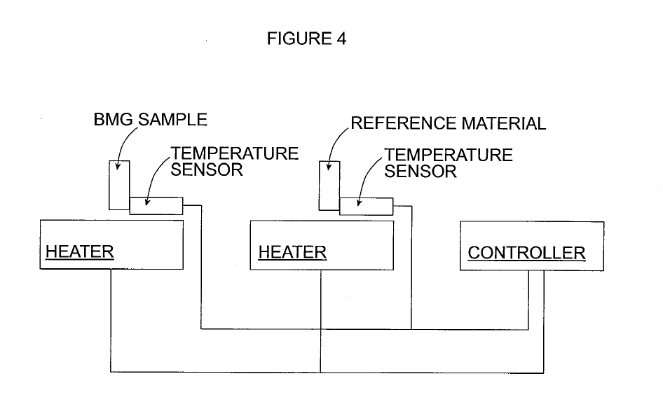

The degree of crystallinity arrived at can be verified by a separate, independent method, including one that is destructive. For example, it can be determined using differential scanning calorimetry (DSC). In one embodiment, after optical inspection and/or hardness measurement, the sampling portion can be subjected to DSC. Note that the process need not be limited to this particular sequence. In one embodiment, the inspection process can further include obtaining a DSC result from the sampling portion; and comparing the result against the result found by the aforementioned hardness measurement and optical inspection technique. In other words, in one embodiment, DSC can service as a separate independent verification process for the other inspection/measurement techniques. FIG. 4 illustrates an apparatus for performing DSC on a sample of bulk amorphous alloy for which the percentage of crystallinity is not known. The apparatus may provide a heating unit for the BMG sample and a heating unit for a reference material. The reference material may be, for example, indium. A controller may be configured to adjust the energy output by the heating units and to measure the energy output. A temperature sensor may also be attached to each of the BMG material and reference material.

The controller may control the heating units to heat the BMG material and reference material at the same rate of temperature increase. For example, if the BMG material has a higher specific heat than the reference material, the controller may increase the energy output of the heating unit heating the BMG material. In one embodiment, the controller may heat both the BMG material and the reference material to a range of 60° C. to 400° C. The controller may also heat both materials at a different range, from a few degrees to a few thousand degrees.

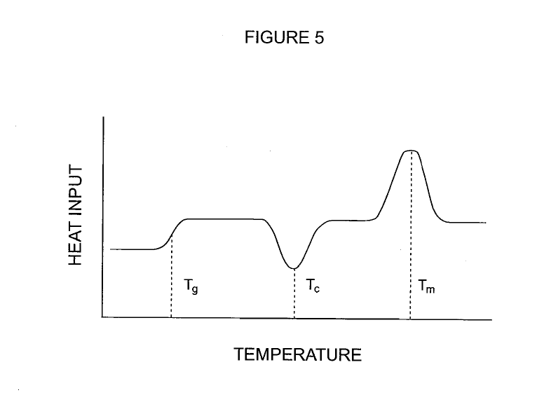

As the controller heats both the BMG material and reference material at the same rate of temperature increase, it may measure the difference in the energy output between the two heating units. FIG. 5 shows a graph of the difference in energy output, more specifically the heat flow, as the BMG material is heated to higher temperatures in one embodiment merely for illustrative purpose. The changes in the energy output may indicate phase transitions or specific heat of the material. A crystallization event or another exothermic event may be identified from decreases in heat flow. A melting event or another endothermic event may be identified from an increase in heat flow. As shown in FIG. 5, a crystallization event may be identified at T_{c}, while a melting event may be identified at Tₘ.

The difference in the energy given off during crystallization and the energy absorbed during melting may be used to calculate the percentage of crystallinity. The difference may reflect less energy given off during crystallization than absorbed during melting because portions that were already crystalline below the crystallization temperature, T_{c}, would not contribute to the energy flow at T_{c}, but would still absorb energy to be melted, at Tₘ.

The energy given off during crystallization may be calculated by integrating the change in heat flow as a function of temperature. In FIG. 5, the integration may be done by calculating the area below the curve at the dip at T_{C}, which may reflect the heat of crystallization, or H_{C}. The energy absorbed during melting may be calculated by integrating the change in heat flow as a function of temperature. In FIG. 5, the integration may be done by calculating the area under curve at the peak at Tₘ, which may reflect the heat of melting, or Hₘ. The difference of Hₘ and H_{c} may reflect the additional energy, H′, required to melt portions of the BMG sample that was already crystalline below T_{C}. The additional energy H′ may be divided by H_{C, 100%}, which is the specific heat of melting one gram of a fully crystalline form of the BMG. The percentage of crystallinity may be indicated by H′/H _{C, 100%}×100.

Thermal conductivity of amorphous materials may be lower than that of the crystalline counterparts. To achieve formation of an amorphous structure even during slower cooling, the alloy may be made of three or more components, leading to complex crystal units with higher potential energy and lower chance of formation. The formation of amorphous alloy can depend on several factors: the composition of the components of the alloy; the atomic radius of the components (preferably with a significant difference of over 12% to achieve high packing density and low free volume); and the negative heat of mixing of the combination of components, inhibiting crystal nucleation and prolonging the time the molten metal stays in a supercooled state. However, as the formation of an amorphous alloy is based on many different variables, it can be difficult to make a prior determination of whether an alloy composition would form an amorphous alloy. The typical values of H _{C 100}% are approximately 120 J/gm to 170 J/gm for Zr-containing BMG alloys.

### Quality Control

The presently described methods can be applied to a plurality of test samples. Alternatively, they can be applied to one sample at different locations thereof For example, the optical inspection and/or hardness measurement can be applied to different locations on a surface of a sample (e.g., the sampling portion) in order to examine the uniformity of the material property. In one embodiment, based on the comparison and determination, the presently described methods can help evaluate the quality of the BMG manufacturing process. The aforedescribed standard can be predetermined or can be determined in the same setting as the test sample evaluation. Any of the processes described herein can be repeated. For example, measuring hardness, optically inspecting, comparing, and/or evaluating can be repeated at multiple locations on a sample or on multiple samples. Thus, in some embodiments, the hardness value referred to herein can refer to an average value with standard deviation.

The techniques described herein can be further extended to detecting defects in a BMG. For example, in one embodiment, the presence of crystal can be considered as defects. A defect may, for example, result in the BMG sample showing a lower hardness or presence of at least one crystal under the microscope. In one embodiment, a database may store a set of hardness values of a BMG of various known crystallinity. To test a BMG sample of the same composition, hardness measurement and/or optical inspection may be applied to the BMG sample. The response of the BMG sample—in the form of one more hardness value and direct optical observation results—may be compared against the set of hardness values corresponding to the known crystallinity in the database. Depending on the number of standard data points in the database, a range, or even a single value of crystallinity of the sample can be derived.

The identification of the defect or flaw can also be integrated to evaluate the quality of the alloy making/forming process, and the feedback therefrom can be used modify and/or improve the process. The alloy forming process referred to herein can further include casting and shaping the alloy into parts of predetermined shape or size. The casting/shaping process can involve, for example, injection molding, die casting, counter gravity casting, suction casting, investment casting, and thermoplastic forming processes. In one embodiment, because the crystal(s) can be considered a defect, the inspection methods described herein can be used to identify defects—e.g., undesirable presence of crystals in an alloy that is intended to be amorphous. For example, in one embodiment, if via the presently described methods crystals are found in a supposed BMG sample that is fully amorphous, or at any pre-designated degree of crystallinity deemed acceptable, the sample can be deemed rejected before it is made into a structural part of a device. In addition to rejecting the sample in the manufacturing process, the manufacturing and/or forming process modified and improved based on the results of the presently described inspection methods.

The presently described methods can be stored in a computer-readable medium and executed by the same in some embodiments. The methods can also be executed by an apparatus, which herein can refer to a single machinery or a system, such as an assembly of machineries. In one embodiment, the apparatus is configured to carry out the method, which involves detecting optically in a sampling portion presence of crystals, the sampling portion is a portion of a part comprising a bulk amorphous alloy; determining a parameter related to the part by a result of the optical detection; measuring a hardness value for the sampling portion; and relating the hardness value to the parameter. In one embodiment, the methods described herein can be automated.

The apparatus can be any of the machinery or equipment that can be used to carry out any of the processes described herein. In one embodiment, the apparatus can become an integral part of a quality control feedback system that can provide feedback to the BMG part fabrication process (or plant) to allow the process to be modified or improved. The parameter herein can include presence of crystals, degree of crystallinity, porosity, presence of occlusions, or combinations thereof.

The inspection need not be carried out in the fabrication machinery, and instead can be carried out in several different locations. For example, optical inspection can be applied to a sample and the results obtained can be taken off-site (or on-site but away from the machinery) for comparison, same applies to hardness measurement and/or DSC observation. In other words, the apparatus that performs the inspection and/or analysis need not be an integral part of the manufacturing system/setup. In one embodiment, a quality control method can be carried out by the following process: obtaining at least one standard parameter from at least one standard alloy sample by measuring the hardness value of the at least one standard alloy sample; obtaining a test parameter from a test alloy sample comprising a bulk amorphous alloy by measuring a hardness value the test alloy sample; and evaluating the test alloy sample by comparing the standard parameter with the test parameter, the “parameter” in this embodiment can refer to hardness value. The different parts of this process can be as described above. The results can be further independently verified. For example, another sample (or the same sample) can be inspected using another method, including a destructive technique, for comparison and/or verification.

What is claimed:

1. A method, comprising:
forming a part comprising a bulk amorphous alloy, wherein the part comprises a sampling portion;
determining a parameter related to the part by detecting presence of crystals of the alloy within an imaging surface of the sampling portion; and
evaluating the part based on the parameter.

2. The method of claim 1, further comprising evaluating the forming based on the parameter.

3. The method of claim 1, further comprising:
obtaining a differential scanning calorimetry result from the sampling portion; and
comparing the result to the parameter.

4. The method of claim 1, wherein the sampling portion is separable from the remainder of the part.

5. The method of claim 1, further comprising measuring hardness of the sampling portion.

6. The method of claim 1, wherein the forming comprises injection molding, die casting, counter gravity casting, suction casting, investment casting, thermoplastic forming processes, or combinations thereof.

7. The method of claim 1, wherein the parameter comprises a degree of crystallinity, porosity, presence of occlusions, or combinations thereof.

8. The method of claim 1, wherein the sampling portion is an excess of the part as a result of the forming.

9. The method of claim 1, wherein the imaging is carried out by metallurgical microscope, polarized optical microscope, an electron microscope, an atomic force microscope, scanning electron microscope, a scan tunneling microscope, or any other type of microscope capable of magnifying an image or combinations thereof.

10. The method of claim 1, wherein the imaging is carried out at a center region of the surface.

11. A method, comprising:
providing a part comprising a bulk amorphous alloy, wherein the part comprises a sampling portion;
detecting by imaging the sampling portion presence of crystals;
determining a parameter related to the part by a result of the imaging;
measuring a hardness value for the sampling portion; and
relating the hardness value to the parameter.

12. The method of claim 11, further comprising separating the sampling portion from the remainder of the part.

13. The method of claim 11, wherein the sampling portion is in a form of a gate.

14. The method of claim 11, wherein the sampling portion has an orthogonal geometry.

15. The method of claim 11, further comprising making the part and evaluating the making based on at least one of the parameter and the hardness value.

16. The method of claim 11, wherein the detecting is carried out by metallurgical microscope, polarized optical microscope, an electron microscope, an atomic force microscope, scanning electron microscope, a scan tunneling microscope, or any other type of microscope capable of magnifying an image or combinations thereof.

17. The method of claim 11, wherein the detecting is carried out at a center region of the sampling portion.

18. The method of claim 11, further comprising evaluating the part based on the parameter.

19. The method of claim 11, wherein the measuring the hardness value is carried out by Vicker's hardness, Rockwell hardness or combinations thereof.

20. The method of claim 11, further comprising making the part into a geometry that has at least one dimension that is greater or equal to a critical thickness of the alloy.

21. An apparatus configured to carry a method comprising:
detecting by imaging in a sampling portion presence of crystals, the sampling portion being a portion of a part comprising a bulk amorphous alloy;
determining a parameter related to the part by a result of the imaging;
measuring a hardness value for the sampling portion; and
relating the hardness value to the parameter.

22. The apparatus of claim 21, wherein the apparatus is a part of a quality control feedback system.
